(19) United States
(12) Patent Application Publication
(10) Pub. No.: US 2025/0159802 A1
(43) Pub. Date: May 15, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Yangje Lee, Suwon-si (KR); Changgon Kim, Suwon-si (KR); Eunsik Kim, Suwon-si (KR); Jesang Park, Suwon-si (KR); Youngil Cho, Suwon-si (KR); Sumin Seo, Suwon-si (KR); Gyeongah Yun, Suwon-si (KR); Sangwuk Jun, Suwon-si (KR)

(73) Assignee: SAMSUNG ELECTRO-MECHANICS CO., LTD., Suwon-si (KR)

(21) Appl. No.: 18/774,619

(22) Filed: Jul. 16, 2024

(30) Foreign Application Priority Data
Nov. 15, 2023 (KR) 10-2023-0158499

(51) Int. Cl. H05K 1/11; H05K 3/28

(52) U.S. Cl. CPC H05K 1/11; H05K 3/28; H05K 2201/09036

(57) ABSTRACT

A printed circuit board includes: insulating layers; a cavity disposed in the insulating layers; contact portions disposed in the cavity; and a dummy layer disposed on a bottom portion of a side wall of the cavity and disposed between the insulating layers. A first thickness of the dummy layer is less than a second thickness of the contact portions.

### CROSS-REFERENCE TO RELATED APPLICATION

This application claims priority to and the benefit of Korean Patent Application No. 10-2023-0158499 filed in the Korean Intellectual Property Office on Nov. 15, 2023, the entire contents of which are incorporated herein by reference.

### TECHNICAL FIELD

The present disclosure relates to a printed circuit board and a manufacturing method thereof.

### BACKGROUND

Printed circuit boards are boards having circuit patterns made of conductive materials such as copper on insulating materials, and as electronic devices in the IT field, including mobile phones, have been miniaturized, a method of forming cavities in a printed circuit board and placing electronic components such as ICs, active components, or passive components in the cavities has been proposed.

The deeper the cavity depth of a printed circuit board is, the more portions of electronic components may be mounted in the cavity, and an entire thickness of the product packaging the electronic components and the printed circuit board may be reduced.

When forming the cavity on the printed circuit board, it is difficult to control the depth of the cavity, a contact pattern for a connection with the electronic components in the cavity may be damaged, and it may be difficult to accurately mount the electronic components in the cavity.

### SUMMARY

The present disclosure attempts to provide a printed circuit board for forming a cavity for increasing installation accuracy without damages to an contact pattern in a cavity with a desired depth, and a manufacturing method thereof.

The object of the present disclosure is not limited to the above-described object, and it may be expanded in various ways in the range of the ideas and the areas of the present disclosure.

An embodiment of the present disclosure provides a printed circuit board including: insulating layers; a cavity disposed in at least a portion of the insulating layers; contact portions disposed in the cavity; and a dummy layer disposed on a bottom portion of a side wall of the cavity and disposed between the insulating layers. A first thickness of the dummy layer is less than a second thickness of the contact portions.

An edge of one of the insulating layers which covers the dummy layer, as an edge of a portion of the side wall of the cavity, may be aligned with an edge of the dummy layer in a height direction that is vertical to an upper surface of one or more of the insulating layers.

The dummy layer may include a first dummy layer and a second dummy layer disposed on the first dummy layer, and an upper side of the second dummy layer may be covered with the insulating layers.

The printed circuit board may further include a seed layer disposed below the contact portions. The first dummy layer may include a same layer as the seed layer.

The first dummy layer and the second dummy layer may include different layers from each other.

An edge of a portion of the side wall of the cavity may be aligned with and edges of the first dummy layer and the second dummy layer in the height direction.

The dummy layer may further include a third dummy layer disposed on a lateral side of the first dummy layer.

The printed circuit board may further include a cover layer disposed on the contact portions, wherein the third dummy layer may include a same layer as the cover layer.

The printed circuit board may further include a seed layer disposed below the contact portions, wherein the dummy layer may include a different layer from the seed layer.

A width of the cavity may not be constant in the height direction.

Another embodiment of the present disclosure provides a method for manufacturing a printed circuit board including: forming contact portions on a first insulating layer; forming a blocking layer on the contact portions; forming insulating layers having a cavity for exposing the blocking layer and covering an edge of the blocking layer; forming a sacrificial layer on the blocking layer in the cavity; removing the sacrificial layer; and forming a dummy layer disposed on a bottom portion of a side wall of the cavity and disposed below the insulating layers by removing the blocking layer exposed by the cavity.

The method may further include forming a seed layer disposed below the contact portions and the blocking layer.

The removing of the sacrificial layer may include removing the seed layer that is not covered by the insulating layers and the contact portions.

The dummy layer may be formed to include a first dummy layer and a second dummy layer disposed on the first dummy layer, and an upper side of the second dummy layer may be covered with the insulating layers.

The first dummy layer may be formed with a same layer as the seed layer, and the second dummy layer may be formed with a same layer as the blocking layer.

The method may further include forming a cover layer on surfaces of the contact portions.

The method may further include forming a third dummy layer of the dummy layer on a lateral side of the first dummy layer.

The third dummy layer may be formed with a same layer as the cover layer.

A width of the cavity may be formed to be not constant in a height direction that is vertical to upper surfaces of the insulating layers.

According to the embodiments, the printed circuit board with a desired depth for forming a cavity for increasing installation accuracy without damages to an contact pattern in a cavity and a manufacturing method thereof may be provided.

The object of the present embodiment is not limited to the above-described object, and it may be expanded in various ways in the range of the ideas and the areas of this disclosure.

### BRIEF DESCRIPTION OF THE DRAWINGS

FIG. 1 shows a cross-sectional view of a printed circuit board according to an embodiment.

FIG. 2 shows an enlarged view of a portion of FIG. 1.

FIG. 3 to FIG. 14 show cross-sectional views on a method for manufacturing a printed circuit board according to an embodiment.

FIG. 15 shows a cross-sectional view on a printed circuit board according to another embodiment.

FIG. 16 shows an enlarged view of a portion of FIG. 15.

FIG. 17 to FIG. 21 show cross-sectional views on a method for manufacturing a printed circuit board according to another embodiment.

### DETAILED DESCRIPTION

The embodiments will be described more fully hereinafter with reference to the accompanying drawings, in which embodiments are shown. As those skilled in the art would realize, the described embodiments may be modified in various different ways, all without departing from the spirit or scope of this disclosure.

Parts that are irrelevant to the description will be omitted to clearly describe this disclosure, and the same elements will be designated by the same reference numerals throughout the specification.

The accompanying drawings are provided only in order to allow embodiments disclosed in the present specification to be easily understood and are not to be interpreted as limiting the spirit disclosed in the present specification, and it is to be understood that this disclosure includes all modifications, equivalents, and substitutions without departing from the scope and spirit of this disclosure.

The size and thickness of each configuration shown in the drawings are arbitrarily shown for better understanding and ease of description, but the present disclosure is not limited thereto. In the drawings, the thickness of layers, films, panels, regions, etc., are exaggerated for clarity. The thicknesses of some layers and areas are exaggerated for convenience of explanation.

It will be understood that when an element such as a layer, film, region, or substrate is referred to as being “on” another element, it may be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

When it is described that a part is “connected” to another part, the part may be “directly connected” to the other element, may be “connected” to the other part through a third part, or may be connected to the other part physically or electrically, and they may be referred to by different titles depending on positions or functions, but respective portions that are substantially integrated into one body may be connected to each other.

Various embodiments and variations will now be described in detail with reference to accompanying drawings.

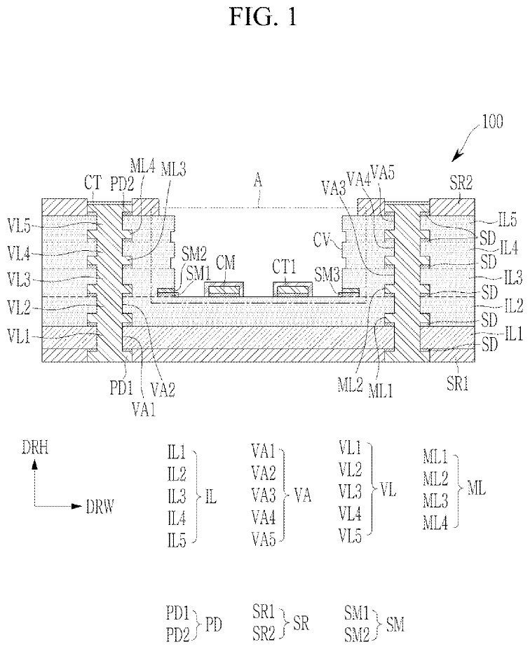

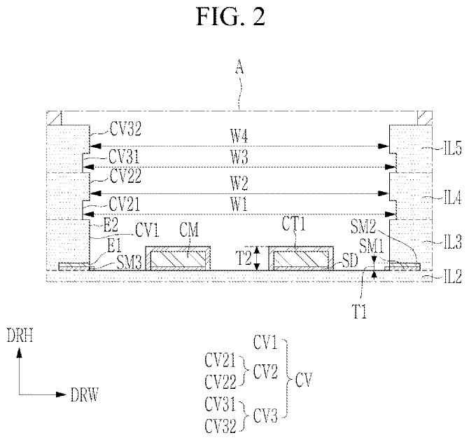

A printed circuit board 100 according to an embodiment will now be described with reference to FIG. 1 and FIG. 2. FIG. 1 shows a cross-sectional view of a printed circuit board according to an embodiment, and FIG. 2 shows an enlarged view of a portion A of FIG. 1.

Referring to FIG. 1 and FIG. 2, the printed circuit board 100 according to the present embodiment may include a plurality of insulating layers IL, a plurality of wire layers ML buried in the insulating layers IL, a plurality of vias VL disposed in via holes VA of the insulating layers IL, a plurality of pad layers PD, a solder resist layer SR, a cavity CV formed in part of the insulating layers IL, contact portions CM disposed in the cavity CV, and a dummy layer SM disposed along a lower edge of the cavity CV.

The plurality of insulating layers IL may include a first insulating layer IL1, a second insulating layer IL2, a third insulating layer IL3, a fourth insulating layer IL4, and a fifth insulating layer IL5 stacked in a height direction DRH.

The wire layers ML may include a first wire layer ML1 buried by the second insulating layer IL2, a second wire layer ML2 buried by the third insulating layer IL3, a third wire layer ML3 buried by the fourth insulating layer IL4, and a fourth wire layer M4 buried by the fifth insulating layer IL5.

The vias VL may include a first via VL1 disposed in the first via hole VA1 formed in the first insulating layer IL1, a second via VL2 disposed in the second via hole VA2 formed in the second insulating layer IL2, a third via VL3 disposed in the third via hole VA3 formed in the third insulating layer IL3, a fourth via VL4 disposed in the fourth via hole VA4 formed in the fourth insulating layer IL4, and a fifth via VL5 disposed in the fifth via hole VA5 formed in the fifth insulating layer IL5.

The pad layers PD may include a first pad layer PD1 disposed below the first insulating layer IL1 and a second pad layer PD2 disposed above the fifth insulating layer IL5.

A portion of the first wire layer ML1 may be connected to the first pad layer PD1 through the first via VL1, a portion of the first wire layer ML1 may be connected to a portion of the second wire layer ML2 through the second via VL2, a portion of the second wire layer ML2 may be connected to a portion of the third wire layer ML3 through the third via VL3, a portion of the third wire layer ML3 may be connected to a portion of the fourth wire layer ML4 through the fourth via VL4, and a portion of the fourth wire layer ML4 may be connected to the second pad layer PD2 through the fifth via VL5.

The solder resist layer SR may include a first solder resist layer SR1 disposed below the first insulating layer IL1 and exposing a portion of the first pad layer PD1, and a second solder resist layer SR2 disposed above the fifth insulating layer IL5 and exposing a portion of the second pad layer PD2.

The cavity CV may be formed in the third insulating layer IL3, the fourth insulating layer IL4, and the fifth insulating layer IL5.

The contact portions CM may be disposed in the cavity CV. The contact portions CM may be formed with a same layer and may have same thickness as the second wire layer ML2 buried in the third insulating layer IL3.

The dummy layer SM may be disposed along a bottom-portion edge of a side wall of the cavity CV, and may include a first dummy layer SM1, a second dummy layer SM2, and a third dummy layer SM3.

The second dummy layer SM2 may be disposed on the first dummy layer SM1, an upper side of the second dummy layer SM2 may be covered with the third insulating layer IL3, and the third dummy layer SM3 may be disposed on a lateral side of the second dummy layer SM2 disposed near the cavity CV.

The first dummy layer SM1 and the second dummy layer SM2 may include different layers. For example, the first dummy layer SM1 may include copper (Cu), and the second dummy layer SM2 may include nickel (Ni), to which the embodiment is not limited.

A cover layer CT may be disposed on the second pad layer PD2, and a first cover layer CT1 may be disposed on the contact portions CM.

The third dummy layer SM3 may be formed with the same layer and may have the same thickness as the first cover layer CT1.

A seed layer SD may be disposed below the wire layers ML and the contact portions CM. The seed layer SD may include metals such as the wire layers ML and the contact portions CM.

Referring to FIG. 2, the cavity CV may include a first cavity CV1 formed in the third insulating layer IL3, second cavities CV21 and CV22 formed in the fourth insulating layer IL4, and third cavities CV31 and CV32 formed in the fifth insulating layer IL5.

The second cavities CV21 and CV22 formed in the fourth insulating layer IL4 may include a first portion CV21 having a first width W1 in a planar direction DRW that is vertical to the height direction DRH and a second portion CV22 having a second width W2 that is different from the first width W1. The first portion CV21 of the second cavity CV2 may be disposed on a lateral side of the third wire layer ML3 buried in the fourth insulating layer IL4 and may have the same thickness as the third wire layer ML3 in the height direction DRH, and the second portion CV22 of the second cavity CV2 may be disposed on a lateral side of the fourth via VL4 disposed in the fourth via hole VA4 formed in the fourth insulating layer IL4 and may have the same thickness as the fourth via VL4 in the height direction DRH. The first width W1 of the first portion CV21 may be greater than the second width W2 of the second portion CV22.

The third cavities CV31 and CV32 formed in the fifth insulating layer IL5 may include a first portion CV31 having a third width W3 and a second portion CV32 having a fourth width W4 that is different from the third width W3 in the planar direction DRW. The first portion CV31 of the third cavity CV3 may be disposed on a lateral side of the fourth wire layer ML4 buried in the fifth insulating layer IL5 and may have the same height as the fourth wire layer ML4 in the height direction DRH, and the second portion CV32 of the third cavity CV3 may be disposed on a lateral side of the fifth via VL5 disposed in the fifth via hole VA5 formed in the fifth insulating layer IL5 and may have the same thickness as the fifth via VL5 in the height direction DRH. A third width W3 of the first portion CV31 may be greater than a fourth width W4 of the second portion CV32.

The dummy layer SM may be disposed along the bottom-portion edge of the side wall of the cavity CV, and the dummy layer SM may include a first dummy layer SM1, a second dummy layer SM2, and a third dummy layer SM3. The second dummy layer SM2 may be disposed on the first dummy layer SM1, an upper side of the second dummy layer SM2 may be covered with the third insulating layer IL3, and the third dummy layer SM3 may be disposed on a lateral side of the second dummy layer SM2. The first dummy layer SM1 and the second dummy layer SM2 may be inserted into the insulating layer IL, and one lateral sides of the first dummy layer SM1 and the second dummy layer SM2 may form part of the side wall of the cavity CV.

The first cover layer CT1 may be disposed on the contact portions CM. The first cover layer CT1 may surround the lateral sides and the upper sides of the contact portions CM.

The third dummy layer SM3 may be disposed on a lateral side of the second dummy layer SM2, and the third dummy layer SM3 may include the same layer and may have the same thickness as the first cover layer CT1.

A first thickness T1 of the first dummy layer SM1 and the second dummy layer SM2 may be less than a second thickness T2 of the contact portions CM.

A first edge E1 of the first dummy layer SM1 and the second dummy layer SM2 may be aligned with a second edge E2 of the first cavity CV1 formed in the third insulating layer IL3 from among the cavity CV in the height direction DRH.

The seed layer SD may be disposed below the contact portions CM, and the first dummy layer SM1 may include the same layer as the seed layer SD disposed below the contact portions CM, and the first dummy layer SM1 may have the same thickness as the seed layer SD.

While the cavity CV is formed, the second dummy layer SM2 may cover the contact portions CM to protect the same, and the second dummy layer SM2 may be removed during the manufacturing process.

According to the printed circuit board according to the present embodiment, the cavity CV may be formed in the insulating layers IL3, IL4, and IL5 from among the insulating layers IL, and the cavity CV with a desired depth may be formed by adjusting the thickness and the number of the insulating layers in which the cavity CV is formed. Further, while the cavity CV is formed, the contact portions CM may be covered and protected by using the second dummy layer SM2, and the second dummy layer SM2 may be removed during the manufacturing process, and the contact portions CM in the cavity CV may not be damaged during forming the cavity CV, thereby preventing an contact characteristic of the semiconductor chip installed in the cavity CV and the contact portions CM from being deteriorated.

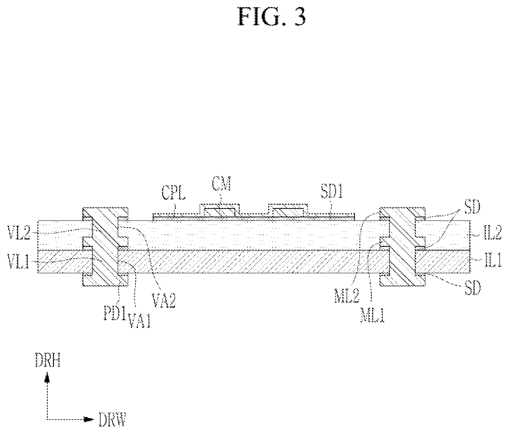

A method for manufacturing a printed circuit board according to an embodiment will now be described with reference to FIG. 3 to FIG. 14 together with FIG. 1 and FIG. 2. FIG. 3 to FIG. 14 show cross-sectional views on a method for manufacturing a printed circuit board according to an embodiment.

Referring to FIG. 3, a second via VL2 disposed in the second via hole VA2 formed in the second insulating layer IL2 and a second wire layer ML2 disposed on the second insulating layer IL2 and connected to the second via VL2 are formed, and a first seed layer SD1 and contact portions CM disposed on the first seed layer SD1 are formed on the second insulating layer IL2. A blocking layer CPL is formed to cover the first seed layer SD1 and the contact portions CM.

The blocking layer CPL may include a metal layer that is different from the first seed layer SD1 and the contact portions CM, and the blocking layer CPL may have an etching rate that is different from those of the first seed layer SD1 and the contact portions CM.

The first seed layer SD1 may be formed together with the seed layer SD disposed below the second wire layer ML2.

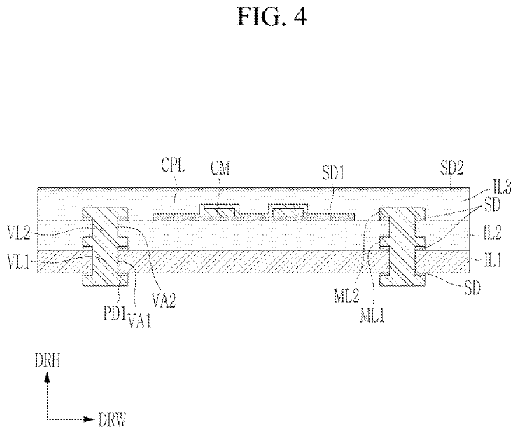

Referring to FIG. 4, the third insulating layer IL3 may be stacked on the second wire layer ML2, the blocking layer CPL, and the second insulating layer IL2, and second seed layer SD2 may be stacked on the third insulating layer IL3.

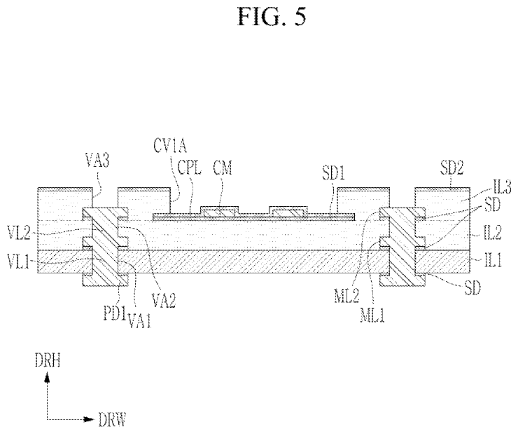

Referring to FIG. 5, by etching the second seed layer SD2 and the third insulating layer IL3, a first hole CV1A is formed on a position where the first cavity CV1 of the cavity CV will be formed, and a third via hole VA3 is formed in the third insulating layer IL3.

An edge portion of the blocking layer CPL and the first seed layer SD1 is not exposed by the first hole CV1A, and the third insulating layer IL3 and the second seed layer SD2 may be disposed on the edge portion of the blocking layer CPL and the first seed layer SD1.

In this instance, the blocking layer CPL covers the first seed layer SD1 and the contact portions CM and protects the same, thereby preventing the contact portions CM from being damaged when the first hole CV1A is formed.

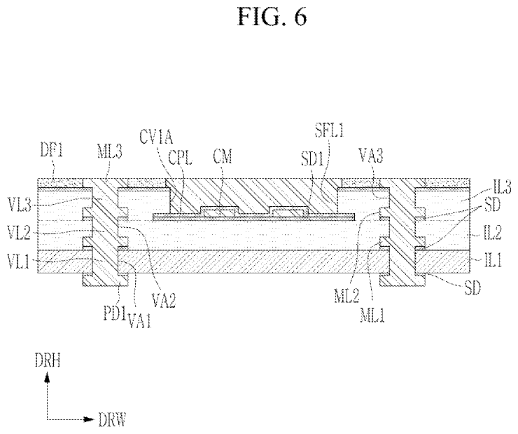

Referring to FIG. 6, a dry film DF1 may be formed on a portion of the second seed layer SD2, a metal layer may be stacked on the second wire layer ML2 and the second seed layer SD2 exposed by the third via hole VA3 formed in the third insulating layer IL3, the metal layer may be patterned, the dry film DF1 may be removed, and the exposed second seed layer SD2 may be removed and therefore a third via VL3 and a third wire layer ML3 may be formed and a first sacrificial layer SFL1 may be formed in the first hole CV1A.

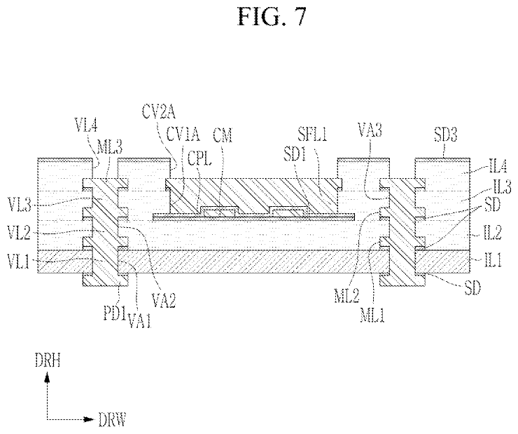

Referring to FIG. 7, the fourth insulating layer IL4 is stacked on the third wire layer ML3, the first sacrificial layer SFL1, and the third insulating layer IL3, and a third seed layer SD3 is stacked on the fourth insulating layer IL4. By etching the third seed layer SD3 and the fourth insulating layer IL4, a second hole CV2A is formed on a position where the second cavity CV2 of the cavity CV will be formed, and a fourth via hole VA4 is formed in the fourth insulating layer IL4. In this instance, the blocking layer CPL and the first sacrificial layer SFL1 cover the first seed layer SD1 and the contact portions CM and protect the same, thereby preventing the contact portions CM from being damaged when the second hole CV2A is formed.

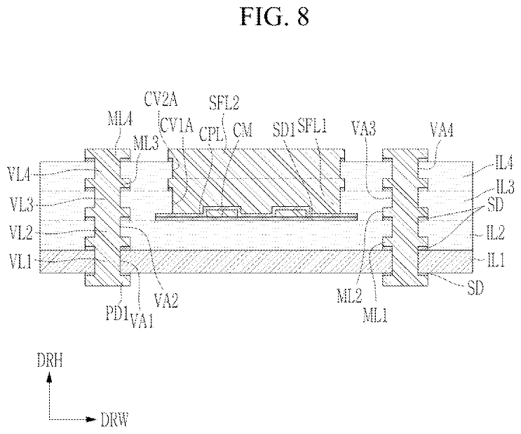

Referring to FIG. 8, a fourth via VL4 connected to the third wire layer ML3 may be formed in the fourth via hole VA4, a fourth wire layer ML4 connected to the fourth via VL4 may be formed on the fourth insulating layer IL4, and a second sacrificial layer SFL2 may be formed in the second hole CV2A.

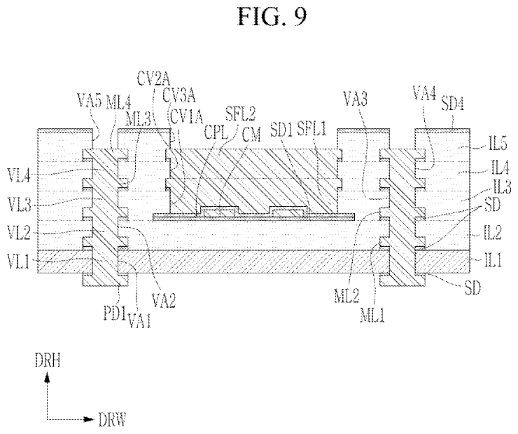

Referring to FIG. 9, the fifth insulating layer IL5 is stacked on the fourth wire layer ML4, the second sacrificial layer SFL2, and the fourth insulating layer IL4, and fourth seed layer SD4 is stacked on the fifth insulating layer IL5. By etching the fourth seed layer SD4 and the fifth insulating layer IL5, a third hole CV3A is formed in a position where a third cavity CV3 of the cavity CV will be formed, and a fifth via hole VA5 is formed in the fifth insulating layer IL5. In this instance, the first sacrificial layer SFL1 and the second sacrificial layer SFL2 together with the blocking layer CPL cover the first seed layer SD1 and the contact portions CM and protect the same, thereby preventing the contact portions CM from being damaged when the third hole CV3A is formed.

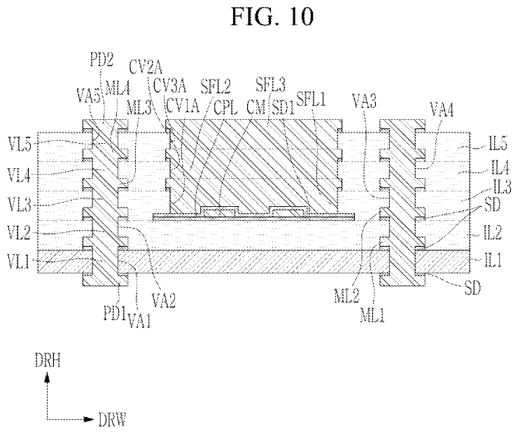

Referring to FIG. 10, a fifth via VL5 connected to the fourth wire layer ML4 may be formed in the fifth via hole VA5, a second pad layer PD2 connected to the fifth via VL5 may be formed on the fifth insulating layer IL5, and a third sacrificial layer SFL3 may be formed in the third hole CV3A.

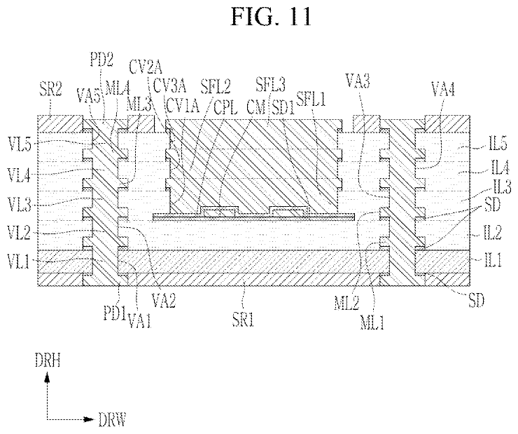

Referring to FIG. 11, a first solder resist layer SR1 for exposing a portion of the first pad layer PD1 may be formed below the first insulating layer IL1, and a second solder resist layer SR2 for exposing a portion of the second pad layer PD2 may be formed above the fifth insulating layer IL5.

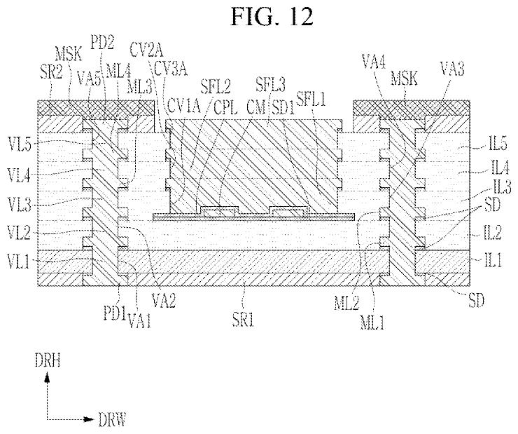

Referring to FIG. 12, a mask layer MSK may be formed on the second solder resist layer SR2. The mask layer MSK may expose the third sacrificial layer SFL3.

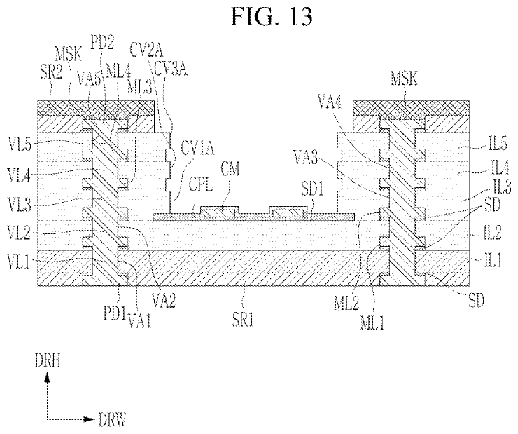

Referring to FIG. 13, a third sacrificial layer SFL3, a second sacrificial layer SFL2, and a first sacrificial layer SFL1 are etched and removed by using the mask layer MSK as an etching mask. In this instance, the blocking layer CPL may cover the first seed layer SD1 and the contact portions CM and may protect the same, thereby preventing the contact portions CM from being damaged.

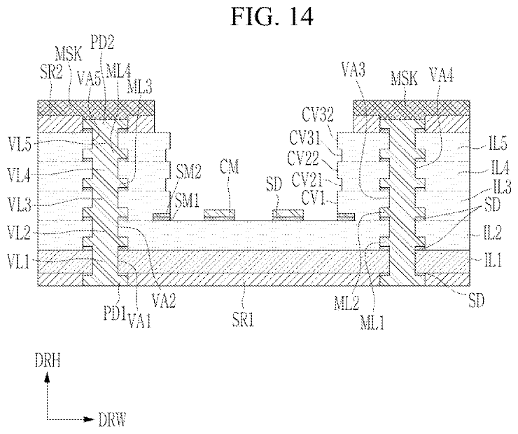

Referring to FIG. 14, the blocking layer CPL and the first seed layer SD1 exposed by the cavity CV are sequentially removed by using the mask layer MSK as an etching mask to form the seed layer SD disposed below the contact portions CM and the first dummy layer SM1 and the second dummy layer SM2 disposed on the edge of the bottom surface of the first cavity CV1.

Exposed portions of the contact portions CM, the second pad layer PD2, and the first dummy layer SM1 may be surface-treated to form a cover layer CT on the second pad layer PD2, a first cover layer CT1 on the contact portions CM, a third dummy layer SM3 on the lateral side of the first dummy layer SM1, and by this, the printed circuit board 100 shown in FIG. 1 and FIG. 2 may be formed.

According to the method for manufacturing a printed circuit board according to the present embodiment, the cavity CV may be formed in the insulating layers IL3, IL4, and IL5 as an example, although the number of the insulating layers in which the cavity CV is formed may be more than or less than that shown in the drawings. Therefore, the cavity CV with the desired thickness may be formed by adjusting the thickness and the number of the insulating layers IL3, IL4, and IL5 in which the cavity CV is formed.

Further, the contact portions CM disposed in the cavity CV are covered and protected with the blocking layer CPL and the sacrificial layers SFL1, SFL2, and SFL3 while the cavity CV is formed so the contact portions CM in the cavity CV may not be damaged while the cavity CV is formed, thereby preventing the contact characteristic of the semiconductor chip and the contact portions CM installed in the cavity CV from being deteriorated.

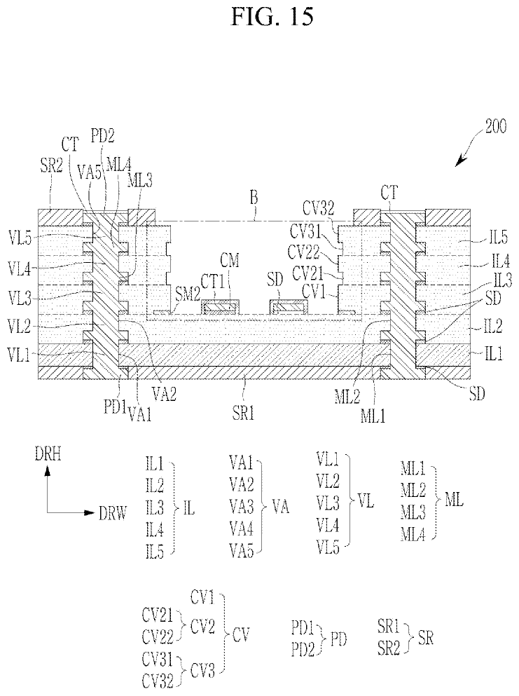

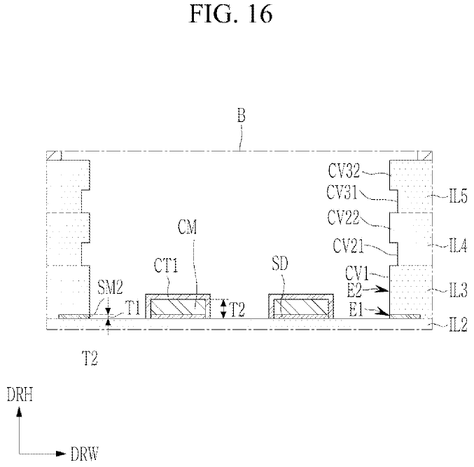

A printed circuit board 200 according to another embodiment will now be described with reference to FIG. 15 and FIG. 16. FIG. 15 shows a cross-sectional view on a printed circuit board according to another embodiment, and FIG. 16 shows an enlarged view of a portion B of FIG. 15.

Referring to FIG. 15, the printed circuit board 200 according to the present embodiment is similar to the printed circuit board 100 according to the previously-described embodiment. No detailed descriptions on the same constituent elements will be provided.

The printed circuit board 200 may include a plurality of insulating layers IL, a plurality of wire layers ML buried in the insulating layers IL, a plurality of vias VL disposed in via holes VA of the insulating layers IL, a plurality of pad layers PD, a solder resist layer SR, a cavity CV formed in a portion of the insulating layers IL, contact portions CM disposed in the cavity CV, and a dummy layer SM2 disposed along the lower edge of the cavity CV.

The insulating layers IL may include a first insulating layer IL1, a second insulating layer IL2, a third insulating layer IL3, a fourth insulating layer IL4, and a fifth insulating layer IL5 stacked in the height direction DRH.

The wire layers ML may include a first wire layer ML1 buried by the second insulating layer IL2, a second wire layer ML2 buried by the third insulating layer IL3, a third wire layer ML3 buried by the fourth insulating layer IL4, and a fourth wire layer M4 buried by the fifth insulating layer IL5.

The vias VL may include a first via VL1 disposed in the first via hole VA1 formed in the first insulating layer IL1, a second via VL2 disposed in the second via hole VA2 formed in the second insulating layer IL2, a third via VL3 disposed in the third via hole VA3 formed in the third insulating layer IL3, a fourth via VL4 disposed in the fourth via hole VA4 formed in the fourth insulating layer IL4, and a fifth via VL5 disposed in the fifth via hole VA5 formed in the fifth insulating layer IL5.

The pad layers PD may include a first pad layer PD1 disposed below the first insulating layer IL1 and a second pad layer PD2 disposed above the fifth insulating layer IL5.

A portion of the first wire layer ML1 may be connected to the first pad layer PD1 through the first via VL1, a portion of the first wire layer ML1 may be connected to a portion of the second wire layer ML2 through the second via VL2, a portion of the second wire layer ML2 may be connected to a portion of the third wire layer ML3 through the third via VL3, a portion of the third wire layer ML3 may be connected to a portion of the fourth wire layer ML4 through the fourth via VL4, and a portion of the fourth wire layer ML4 may be connected to the second pad layer PD2 through the fifth via VL5.

The solder resist layer SR may include a first solder resist layer SR1 disposed below the first insulating layer IL1 and exposing a portion of the first pad layer PD1, and a second solder resist layer SR2 disposed above the fifth insulating layer IL5 and exposing a portion of the second pad layer PD2.

The cavity CV may be formed in the third insulating layer IL3, the fourth insulating layer IL4, and the fifth insulating layer IL5.

The contact portions CM may be disposed in the cavity CV. The contact portions CM may be formed with the same layer and may have the same thickness as the second wire layer ML2 buried in the third insulating layer IL3.

The second dummy layer SM2 may be disposed along the edge of the bottom portion of the side wall of the cavity CV. The printed circuit board 200 according to the present embodiment is different from the printed circuit board 100 according to the previously-described embodiment in that it does not include the first dummy layer SM1 include the same layer as the seed layer SD and the third dummy layer SM3 include the same layer as the cover layer CT and the first cover layer CT1.

An upper side of the second dummy layer SM2 may be covered with the third insulating layer IL3, and the second dummy layer SM2 may include nickel (Ni), and the embodiment is not limited thereto.

The second dummy layer SM2 may be inserted into the insulating layer IL, and one lateral side of the second dummy layer SM2 may configure a portion of the side wall of the cavity CV.

The cavity CV may include a first cavity CV1 formed in the third insulating layer IL3, second cavities CV21 and CV22 formed in the fourth insulating layer IL4, and third cavities CV31 and CV32 formed in the fifth insulating layer IL5.

The second cavities CV21 and CV22 formed in the fourth insulating layer IL4 may include a first portion CV21 having a first width W1 in the planar direction DRW that is vertical to the height direction DRH and a second portion CV22 having a second width W2 that is different from the first width W1. The first portion CV21 of the second cavity CV2 may be disposed on a lateral side of the third wire layer ML3 buried in the fourth insulating layer IL4 and may have the same thickness as the third wire layer ML3 in the height direction DRH, and the second portion CV22 of the second cavity CV2 may be disposed on a lateral side of the fourth via VL4 disposed in the fourth via hole VA4 formed in the fourth insulating layer IL4 and may have the same thickness as the fourth via VL4 in the height direction DRH. The first width W1 of the first portion CV21 may be greater than the second width W2 of the second portion CV22.

The third cavities CV31 and CV32 formed in the fifth insulating layer IL5 may include a first portion CV31 having a third width W3 in the planar direction DRW and a second portion CV32 having a fourth width W4 that is different from the third width W3 in the planar direction DRW. The first portion CV31 of the third cavity CV3 may be disposed on a lateral side of the fourth wire layer ML4 buried in the fifth insulating layer IL5 and may have the same height as the fourth wire layer ML4 in the height direction DRH, and the second portion CV32 of the third cavity CV3 may be disposed on a lateral side of the fifth via VL5 disposed in the fifth via hole VA5 formed in the fifth insulating layer IL5 and may have the same thickness as the fifth via VL5 in the height direction DRH. The third width W3 of the first portion CV31 may be greater than the fourth width W4 of the second portion CV32.

The first thickness T1 of the second dummy layer SM2 may be less than the second thickness T2 of the contact portions CM.

The first edge E1 of the second dummy layer SM2 may be aligned with the second edge E2 of the first cavity CV1 formed in the third insulating layer IL3 from among the cavity CV in the height direction DRH.

While the cavity CV is formed, the second dummy layer SM2 may cover the contact portions CM and may protect the same, and the second dummy layer SM2 may be removed during the manufacturing process.

According to the printed circuit board according to the present embodiment, the cavity CV may be formed in the insulating layers IL3, IL4, and IL5 from among the insulating layers IL, and the cavity CV with a desired depth may be formed by adjusting the thickness and the number of the insulating layers in which the cavity CV is formed. Further, while the cavity CV is formed, the second dummy layer SM2 may be used to cover the contact portions CM and protect the same, and the second dummy layer SM2 may be removed during the manufacturing process, and hence, the contact portions CM in the cavity CV may not be damaged during forming the cavity CV, thereby preventing the contact characteristic of the semiconductor chip and the contact portions CM installed in the cavity CV from being deteriorated.

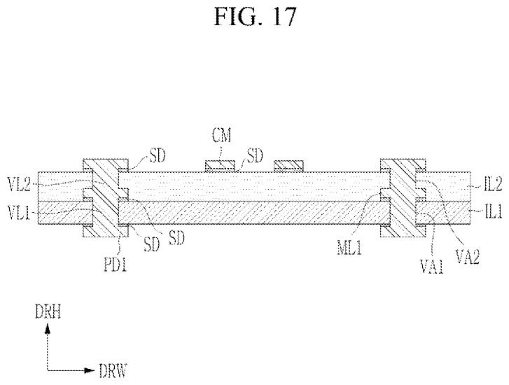

A method for manufacturing a printed circuit board according to another embodiment will now be described with reference to FIG. 17 to FIG. 21 together with FIG. 15 and FIG. 16. FIG. 17 to FIG. 21 show cross-sectional views on a method for manufacturing a printed circuit board according to another embodiment.

Referring to FIG. 17 to FIG. 21, the method for manufacturing a printed circuit board according to the present embodiment is similar to the method for manufacturing a printed circuit board according to the previously described present embodiment. No detailed descriptions on the same manufacturing process will be provided.

Referring to FIG. 17, when a second wire layer ML2 is formed on the second insulating layer IL2, the portion that is not disposed below the contact portions CM from among the first seed layer SD1 may be removed, thereby forming a seed layer SD below the contact portions CM.

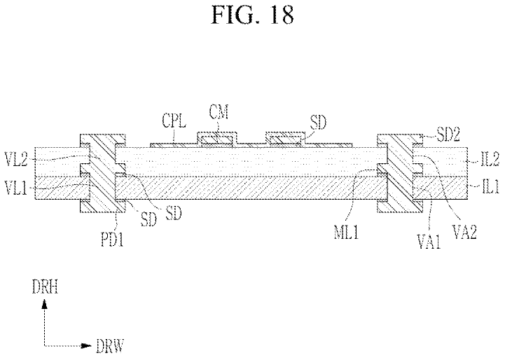

Referring to FIG. 18, a blocking layer CPL for covering the contact portions CM may be formed on the second insulating layer IL2.

The blocking layer CPL may include a metal layer that is different from the seed layer SD and the contact portions CM, and the blocking layer CPL may have the etching rate that is different from those of the seed layer SD and the contact portions CM.

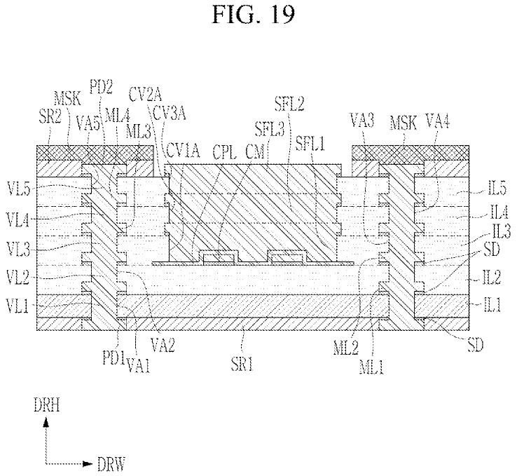

Referring to FIG. 19, a third insulating layer IL3, a fourth insulating layer IL4, a fifth insulating layer IL5, a third via hole VA3, a fourth via hole VA4, a fifth via hole VA5, a third via VL3, a fourth via VL4, a fifth via VL5, a second pad layer PD2, a first sacrificial layer SFL1, a second sacrificial layer SFL2, a third sacrificial layer SFL3, solder resist layers SR1 and SR2, and a mask layer MSK may be formed. The third insulating layer IL3, the fourth insulating layer IL4, and the fifth insulating layer IL5 may be disposed on an edge portion of the blocking layer CPL.

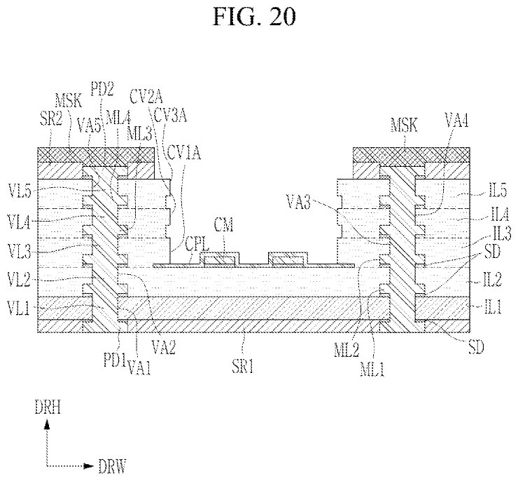

Referring to FIG. 20, the third sacrificial layer SFL3, the second sacrificial layer SFL2, and the first sacrificial layer SFL1 may be etched and removed by using the mask layer MSK as an etching mask. In this instance, the blocking layer CPL may cover the contact portions CM and may protect the same, thereby preventing the contact portions CM from being damaged.

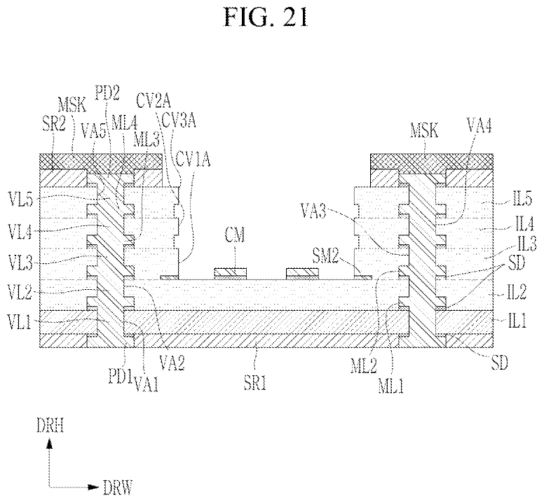

Referring to FIG. 21, the blocking layer CPL exposed by the cavity CV is etched and removed by using the mask layer MSK as an etching mask to form a second dummy layer SM2 disposed bottom-surface edge of the first cavity CV1.

The exposed portions of the contact portions CM and the second pad layer PD2 are surfaced-treated to form a cover layer CT on the second pad layer PD2 and a first cover layer CT1 on the contact portions CM, and by this, the printed circuit board 100 shown in FIG. 15 and FIG. 16 may be formed.

According to the method for manufacturing a printed circuit board according to the present embodiment, the cavity CV may be formed in the insulating layers IL3, IL4, and IL5 as an example, although the number of the insulating layers in which the cavity CV is formed may be more than or less than that shown in the drawings. Therefore, the cavity CV with the desired thickness may be formed by adjusting the thickness and the number of the insulating layers IL3, IL4, and IL5 in which the cavity CV is formed.

Further, the contact portions CM disposed in the cavity CV are covered and protected by the blocking layer CPL and the sacrificial layers SFL1, SFL2, and SFL3 while the cavity CV is formed, so the contact portions CM in the cavity CV may not be damaged while the cavity CV is formed, thereby preventing the contact characteristic of the semiconductor chip and the contact portions CM installed in the cavity CV from being deteriorated.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A printed circuit board comprising:
insulating layers;
a cavity disposed in at least a portion of the insulating layers;
contact portions disposed in the cavity; and
a dummy layer disposed on a bottom portion of a side wall of the cavity and disposed between the insulating layers,
wherein a first thickness of the dummy layer is less than a second thickness of the contact portions.

2. The printed circuit board of claim 1, wherein
an edge of one of the insulating layers which covers the dummy layer, as an edge of a portion of the side wall of the cavity, is aligned with an edge of the dummy layer in a height direction that is vertical to an upper surface of the insulating layers.

3. The printed circuit board of claim 1, wherein
the dummy layer includes a first dummy layer and a second dummy layer disposed on the first dummy layer, and
an upper side of the second dummy layer is covered with one or more of the insulating layers.

4. The printed circuit board of claim 3, further comprising
a seed layer disposed below the contact portions,
wherein the first dummy layer includes a same layer as the seed layer.

5. The printed circuit board of claim 4, wherein
the first dummy layer and the second dummy layer include different layers from each other.

6. The printed circuit board of claim 5, wherein
an edge of a portion of the side wall of the cavity is aligned with edges of the first dummy layer and the second dummy layer in a height direction that is vertical to an upper surface of the insulating layers.

7. The printed circuit board of claim 5, wherein
the dummy layer further includes a third dummy layer disposed on a lateral side of the first dummy layer.

8. The printed circuit board of claim 7, further comprising
a cover layer disposed on the contact portions,
wherein the third dummy layer include a same layer as the cover layer.

9. The printed circuit board of claim 1, further comprising
a seed layer disposed below the contact portions,
wherein the dummy layer includes a different layer from the seed layer.

10. The printed circuit board of claim 9, wherein
an edge of a portion of the side wall of the cavity is aligned with an edge of the dummy layer in a height direction that is vertical to an upper surface of the insulating layers.

11. The printed circuit board of claim 1, wherein
a width of the cavity is not constant in a height direction that is vertical to an upper surface of the insulating layers.

12. A method for manufacturing a printed circuit board, the method comprising:
forming contact portions on a first insulating layer;
forming a blocking layer on the contact portions;
forming insulating layers having a cavity for exposing the blocking layer and covering an edge of the blocking layer;
forming a sacrificial layer on the blocking layer in the cavity;
removing the sacrificial layer; and
forming a dummy layer disposed on a bottom portion of a side wall of the cavity and disposed below the insulating layers by removing the blocking layer exposed by the cavity.

13. The method of claim 12, further comprising
forming a seed layer disposed below the contact portions and the blocking layer.

14. The method of claim 13, wherein
the removing of the sacrificial layer includes removing the seed layer that is not covered by the insulating layers and the contact portions.

15. The method of claim 14, wherein
the dummy layer includes a first dummy layer and a second dummy layer disposed on the first dummy layer, and
an upper side of the second dummy layer is covered with the insulating layers.

16. The method of claim 15, wherein
the first dummy layer is formed with a same layer as the seed layer, and
the second dummy layer is formed with a same layer as the blocking layer.

17. The method of claim 15, further comprising
forming a cover layer on surfaces of the contact portions.

18. The method of claim 17, further comprising
forming a third dummy layer of the dummy layer further on a lateral side of the first dummy layer.

19. The method of claim 18, wherein
the third dummy layer is formed with a same layer as the cover layer.

20. The method of claim 12, wherein
a width of the cavity is formed to be not constant in a height direction that is vertical to upper surfaces of the insulating layers.
